(19) United States
(12) Patent Application Publication
(10) Pub. No.: US 2010/0007390 A1
(43) Pub. Date: Jan. 14, 2010

(54) Clock generating circuit, power converting system, and related method with spread spectrum for EMI reduction

(76) Inventor: Wen-Chung Yeh, Hsin-Chu (TW)

Correspondence Address: NORTH AMERICA INTELLECTUAL PROPERTY CORPORATION, P.O. BOX 506, MERRIFIELD, VA, 22116, US

(21) Appl. No.: 12/406,098

(22) Filed: Mar. 17, 2009

(30) Foreign Application Priority Data
Jul. 10, 2008 (TW) 097126066

(51) Int. Cl. H03L 7/06; H03L 7/00

(52) U.S. Cl. 327/158; 327/161

(57) ABSTRACT

A clock signal generating circuit includes a main delay circuit and a variable delay circuit. The main delay circuit receives a feedback clock signal, and outputs an output clock signal after a first delay when receiving the feedback clock signal. The variable delay circuit receives the output clock signal, and updates the feedback clock signal after a second delay when receiving the output clock signal. The second delay is periodically varied and is shorter than the first delay.

### BACKGROUND OF THE INVENTION

1. Field of the Invention

The present invention relates to a clock generating circuit and related method, and more particularly, to a clock generating circuit and related method with spread spectrum for EMI reduction.

2. Description of the Prior Art

Power converters are required in electronic devices for transforming the received power for use in the electronic devices. The power converter may be implemented by a switching regulator. Clock signal generators are required in some switching regulators to generate clock signals with fixed frequency to turn on/off power switches. Hence the power switches easily generate electromagnetic interference (EMI) that effects the operation of circuit components connected to the switching regulators. Therefore, it is important in design of power management to consider about reducing the EMI generated by the switching regulator.

Conventionally, it is adopted by many power management designers to periodically change the value of charging/discharging current within the clock signal generator, such that the spread spectrum in frequencies of the clock signal generator is achieved. It is also achievable by changing the capacitor within the clock signal generator periodically to reduce the EMI generated by the clock signal.

### BRIEF DESCRIPTION OF THE DRAWINGS

FIG. 1 is a circuit diagram of a clock signal generating circuit with spread spectrum to reduce EMI according to a first embodiment of the present invention.

FIG. 2 is a circuit diagram of a clock signal generating circuit with spread spectrum to reduce EMI according to a second embodiment of the present invention.

FIG. 3 is a diagram of a switching regulator of the present invention.

### DETAILED DESCRIPTION

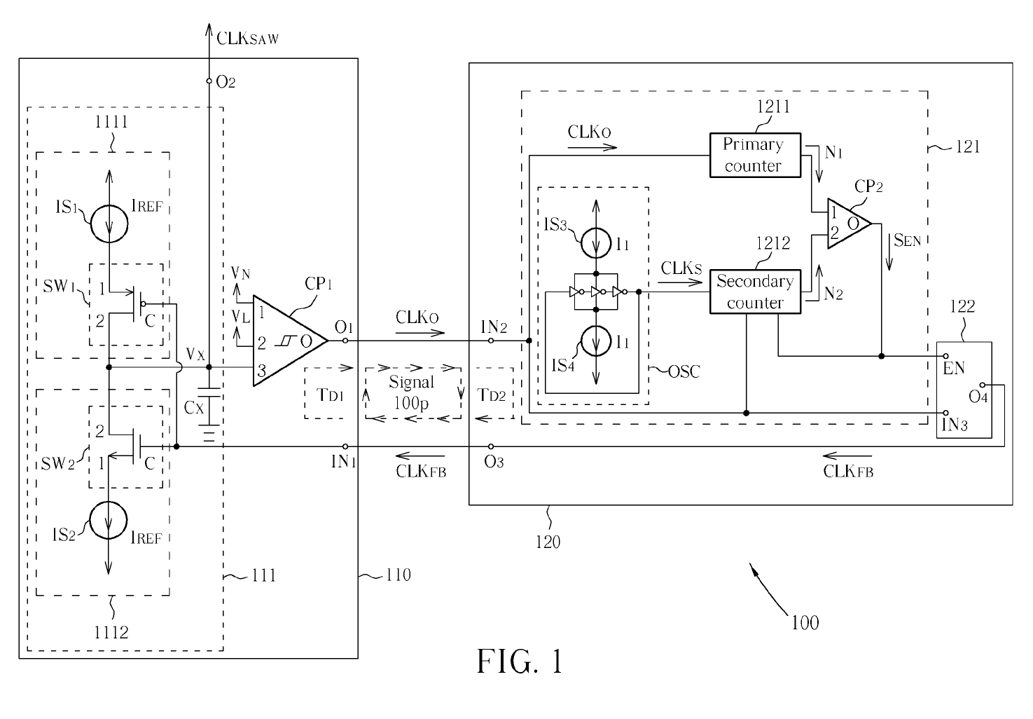

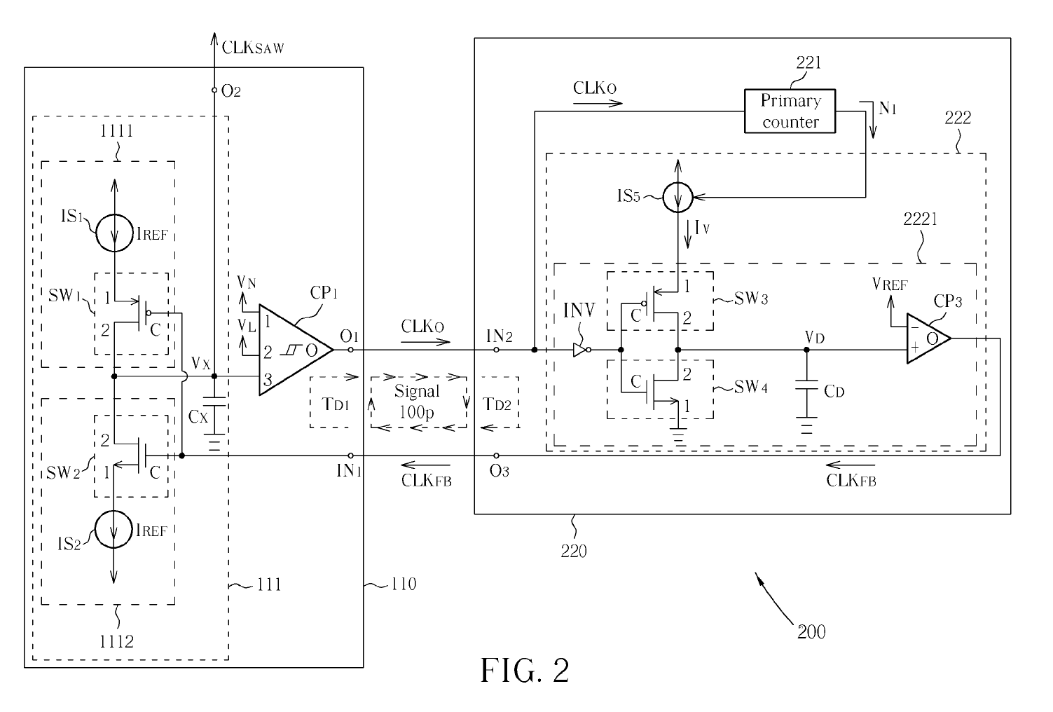

Please refer to FIG. 1 and FIG. 2. FIG. 1 and FIG. 2 are circuit diagrams of clock signal generating circuits 100 and 200 with spread spectrum to reduce EMI according to a first embodiment and a second embodiment of the present invention respectively. As illustrated in FIG. 1, clock signal generating circuit 100 comprises a main delay circuit 110 and a variable delay circuit 120. As shown in FIG. 2, clock signal generating circuit 200 comprises a main delay circuit 110 and a variable delay circuit 220. The basic operation principle is illustrated as bellow with reference to FIG. 1. The basic operation principle is applicable to FIG. 2 as well and will not be repeated again for brevity.

Main delay circuit 110 is used to generate output clock signal CLK_{O} according to feedback clock signal CLK_{FB} after a delay T_{D1}. In other words, there is a delay T_{D1} for main delay circuit 110 from receiving feedback clock signal CLK_{FB} to generate the corresponding output clock signal CLK_{O} in accordance, for signal propagation. In FIG. 1, feedback clock signal CLK_{FB} will cause a corresponding output clock signal CLK_{O} with a logic level opposite to that of feedback clock signal CLK_{FB}.

There is a delay T_{D2} for variable delay circuit 120 from receiving output clock signal CLK_{O} to generate the corresponding feedback clock signal CLK_{FB} in accordance, for signal propagation. In FIG. 1, output clock signal CLK_{O} and its corresponding feedback clock signal CLK_{FB} have the same logic level. However, delay T_{D2} varies periodically, and delay T_{D2} is shorter than delay T_{D1}. In this way, feedback clock signal CLK_{FB} is fed back to main delay circuit 110 after being delayed. In other words, a signal loop is constructed from the output end of main delay circuit 110, through the input end of variable delay circuit 120, the output end of variable delay circuit 120, to the input end of main delay circuit 110. It is seen as a first propagation path from the input end of main delay circuit 110 to the output end of main delay circuit 110. It is further seen as a second propagation path from the input end of variable delay circuit 120 to the output end of variable delay circuit 120. The first propagation path and the second propagation path together form the aforementioned signal loop. The delay due signal propagation in the first propagation path is T_{D1} and the delay due signal propagation in the second propagation path is T_{D2}. As a clock signal generating circuit, the loop gain of the signal loop has to equal −1.

The cycle of clock signals CLK_{O} and CLK_{FB} of clock signal generating circuit 100 is about (T_{D1}+T_{D2}), or approximately equal to T_{D1} plus a minor disturbance T_{D2}. For T_{D2} is adjusted periodically, the frequency of clock signals CLK_{O} and CLK_{FB} is disturbed periodically, such that the power of the generated electromagnetic interference (EMI) does not focus at a single center frequency but is spread averagely within a range around the center frequency. Therefore, the clock signal generating circuit of the embodiment in FIG. 1 is able to generate the output clock signal for EMI reduction.

Please continue referring to FIG. 1. Main delay circuit 110 comprises two output ends O₁ and O₂, an input end IN₁, a comparator CP₁, and a periodic voltage control circuit 111. For a conventional saw-tooth waveform generator, input end IN₁ of main delay circuit 110 would be connected to output end O₁ directly to periodically switch a charging circuit 1111 or a discharging circuit 1112 in order to charge/discharge period capacitor Cₓ and generate saw-tooth waveform signal CLK_{SAW} at output end O₂. Therefore, the difference between main delay circuit 110 and the conventional saw-tooth waveform generator is that in FIG. 1, input end IN₁ and output end O₁ are not directly connected but indirectly connected through variable delay circuit 120. The detail of the operation principle of main delay circuit 110 is not repeated here.

Please continue referring to FIG. 1. Variable delay circuit 120 comprises a delay decision circuit 121 and a pass/hold device 122. Delay decision circuit 121 decides the length of delay T_{D2} according to the number of times of receiving output clock signal CLK_{O}. Besides, delay decision circuit 121 sends out a passing signal to pass/hold device 122 after delay T_{D2}. Pass/hold device 122 then updates feedback clock signal CLK_{FB} using the received output clock signal CLK_{O}, or outputs the received output clock signal CLK_{O} as feedback clock signal CLK_{FB}. During delay T_{D2}, pass/hold device 122 holds feedback clock signal CLK_{FB}, keeping it unchanged.

Delay decision circuit 121 comprises a primary counter 1211, a secondary counter 1212, an oscillator OSC and a comparator CP₂. Pass/hold device 122 may be implemented by a D latch comprising an enabling end EN, an input end IN₃ and an output end O₄.

Primary counter 1211 receives output clock signal CLK_{O}, and calculates the number of cycles that the received output clock signal CLK_{O} passes (e.g. number of rising/falling edges of output clock signal CLK_{O}) in order to generate a count N₁. For example, count N₁ increases by 1 when output clock signal CLK_{O} changes from logic 0 to logic 1. Count N₁ is received by input end 1 of comparator CP₂. Primary counter 1211 may be an auto-reset counter. For example, when count N₁ reaches a limit N_{L}, primary counter 1211 may reset count N₁ to 0 for refreshing. The way how delay T_{D2} is positively correlative to count N₁ will be illustrated later. Since primary counter 1211 is able to automatically reset, delay T_{D2} may vary periodically.

Oscillator OSC comprises two current sources IS₃ and IS₄, and an odd number (for example, 3) of inverters. Current sources IS₃ and IS₄ provide current I₁ to the inverter(s) in oscillator OSC respectively, and are capable of deciding the cycle time of the signal generated from the oscillator OSC. As illustrated in FIG. 1, oscillator OSC may be a ring oscillator, capable of generating a reference clock signal CLK_{S}. Please be noted that the cycle time of reference clock signal CLK_{S} is not greater than delay T_{D2}.

Secondary counter 1212 is electrically connected to oscillator OSC, input end IN₂ of delay decision circuit 120, input end 2 of comparator CP₂, and output end O of comparator CP₂. When secondary counter 1212 receives output clock signal CLK_{O}, secondary counter 1212 starts to count times of reference clock signal CLK_{S} for generating a count N₂, which is received by input end 2 of comparator CP₂.

When counts N₁ and N₂ meet a predetermined condition, such as counts N₁ and N₂ are equal, comparator CP₂ outputs enabling signal S_{EN} through output end O of comparator CP₂ to secondary counter 1212 and pass/hold device 122.

When secondary counter 1212 receives enabling signal S_{EN}, secondary counter 1212 resets count N₂, for example, to 0. Secondary counter 1212 recounts next time when receiving output clock signal CLK_{O}.

Before pass/hold device 122 receives enabling signal S_{EN}, pass/hold device 122 maintains the signal at the output end O of pass/hold device 122 according to the previously received output clock signal CLK_{O}. That is, feedback clock signal CLK_{FB} is not updated. On the contrary, when pass/hold device 122 receives enabling signal S_{EN}, pass/hold device 122 directly outputs the currently received output clock signal CLK_{O}, updating feedback clock signal CLK_{FB}.

Enabling signal is sent out when N₂ equals N₁. N₂ equals N₁ when secondary counter 1212 counts reference clock signal CLK_{S} for N₁ times. Therefore, delay T_{D2} equals the cycle time of clock signal CLK_{S} times N₁, while count N₁ may change along with the number of cycles of output clock signal CLK_{O}.

It may be designed that either rising or falling edge of output clock signal CLK_{O} is delayed by variable delay circuit 120 and the other is not. In another embodiment, both rising and falling edges of output clock signal CLK_{O} are delayed by variable delay circuit 120.

Therefore, the spread spectrum of output clock signal CLK_{O} may be reached by variable delay circuit 120 in FIG. 1 by periodically changing the delay (T_{D2}) of the signal propagation, and the electromagnetic interference (EMI) is reduced in accordance. Similarly, the spectrum of saw-tooth waveform signal CLK_{SAW} can be spread out by variable delay circuit 120, and the EMI is reduced in accordance.

Please continue referring to FIG. 2. Variable delay circuit 220 comprises a primary counter 221 and an auxiliary variable delay circuit 222. Auxiliary variable delay circuit 222 comprises an adjustable current source IS₅ and a signal delay circuit 2221.

The internal structure of primary counter 221 shown in FIG. 2 may be the same as or similar to that of primary counter 1211 in FIG. 1. Primary counter 221 outputs count N₁, which decides the magnitude of current I_{V} of adjustable current source IS₅. For example, count N₁ may represent the decrease of current I_{V} (I_{V}=I₀−N₁I_{d}). Current I_{V} is in charge of charging delay capacitor C_{D} and decides the delay of the signals in signal delay circuit 2221. Therefore, the length of delay T_{D2} of variable delay circuit 220 is positively correlative to count N₁.

Adjustable current source IS₅ can be seen as a Digital/Analog Converter (DAC) IS₅, for converting count N₁ to current I_{V} with the corresponding magnitude (an analog signal).

Signal delay circuit 2221 comprises an inverter INV, two switches SW₃ and SW₄, a delay capacitor CD and a comparator CP₃.

Adjustable current source IS₅ provides current I_{V} to charge delay capacitor CD via switch SW₃ in order to increase delay voltage V_{D}. The larger the current I_{V} provided by adjustable current source IS₅ is, the faster delay capacitor CD is charged, and the faster the output of comparator CP₃ transits. The output of comparator CP₃ is taken as feedback clock signal CLK_{FB}. Therefore, when output clock signal CLK_{O} is rising from a logic low level to a logic high level, the signal propagation time from output clock signal CLK_{O} to feedback clock signal CLK_{FB} depends on current I_{V}, and is positively correlative to the value of count N₁. On the contrary, when output clock signal CLK_{O} is falling, the signal propagation time from output clock signal CLK_{O} to feedback clock signal CLK_{FB} is independent of current I_{V}, and is about a fixed value. Count N₁ is varied periodically, such that the signal propagation time in signal delay circuit 2221 varies periodically.

Therefore, the spread spectrum of the output clock signal CLK_{O} and saw-tooth waveform signal CLK_{SAW} is achieved by periodically changing the delay (T_{D2}) for signal propagation by the variable delay circuit 220. Hence the EMI may be reduced.

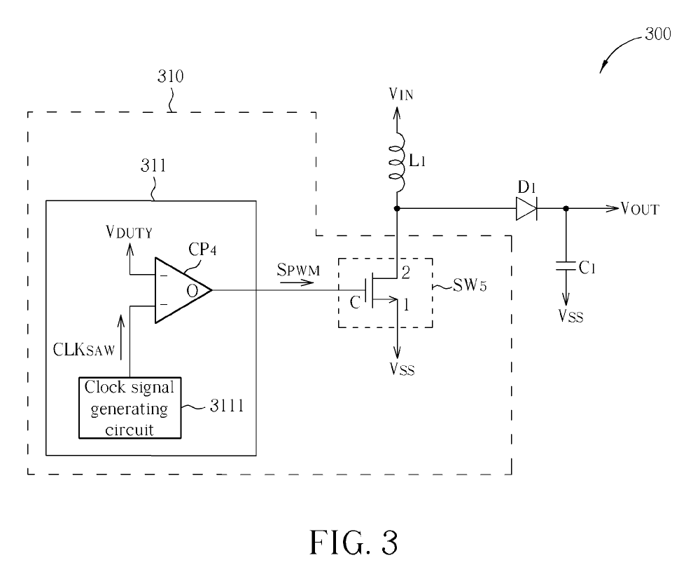

Please refer to FIG. 3. FIG. 3 is a diagram of a switching regulator 300 utilizing one clock signal generating circuit embodying the present invention. As illustrated in FIG. 3, switching regulator 300 comprises a power management system 310, an inductor L₁, a diode D₁ and a capacitor C₁. Switching regulator 300 converts an input power V_{IN} to an output power V_{OUT}. In FIG. 3, switching regulator 300 is a voltage booster.

Power management system 310 comprises a power switch SW₅ and a duty ratio regulator 311. In this embodiment, power switch SW₅ may be an N channel Metal Oxide Semiconductor (NMOS) transistor. Duty ratio regulator 311 comprises a clock signal generating circuit 3111 and a comparator CP₄.

Clock signal generating circuit 311 1 can be implemented by clock signal generating circuit 100 or 200 in FIGS. 1 or 2, to generate a saw-tooth waveform signal CLK_{SAW} with spread spectrum for reducing EMI.

The principle how switching regulator 300 boosts is not a key point of the present invention, and is well known to the people skilled in the art.

The clock signal generating circuit provided by the embodiments of the present invention may be applied to different kinds of switching regulators, such as a voltage bulk circuit or a voltage bulk/boost circuit. The circuit in the example of the present invention is only an exemplary embodiment but not a limitation. The present invention can be applied to any other devices for generating clock signal as well. The spectrum of the output clock signals is spread according to the output value of a digital counter to reduce the EMI.

In summary, by the clock signal generating circuits of the exemplified embodiments, the delay of signal propagation can be varied periodically to spread the spectrum of the output clock signals and further to reduce the EMI. Therefore, by utilizing the clock signal generating circuit of the present invention, the voltage converting circuit is free from the problem of EMI.

Those skilled in the art will readily observe that numerous modifications and alterations of the device and method may be made while retaining the teachings of the invention.

What is claimed is:

1. A clock signal generating circuit with spread spectrum for EMI reduction, the clock signal generating circuit comprising:
a main delay circuit for receiving a feedback clock signal, and outputting an output clock signal after a first delay; and
a variable delay circuit for receiving the output clock signal and updating the feedback clock signal after a second delay;
wherein the second delay is periodically varied and is shorter than the first delay.

2. The clock signal generating circuit of claim 1, wherein the variable delay circuit comprises:
a delay decision circuit for receiving the output clock signal to decide the second delay; and
a pass/hold device, controlled by the delay decision circuit, the pass/hold device updating the feedback clock signal according to the output clock signal after the second delay after receiving the output clock signal; the pass/hold device preventing from updating the feedback clock signal within the second delay after receiving the output clock signal.

3. The clock signal generating circuit of claim 2, wherein the delay decision circuit comprises:
a primary counter, for counting times of receiving the output clock signal to generate a first count in accordance;
wherein the second delay is positively correlative to the first count.

4. The clock signal generating circuit of claim 2, wherein the delay decision circuit further comprises:
an oscillator, for generating a reference clock signal;
a secondary counter, for counting times of receiving the reference clock signal to generate a second count after receiving a current output clock signal; and
a comparator, comparing the first count and the second count, the comparator controlling the pass/hold device to update the feedback clock signal.

5. The clock signal generating circuit of claim 4, wherein the oscillator is a ring oscillator.

6. The clock signal generating circuit of claim 4, wherein the pass/hold device may be a D latch.

7. The clock signal generating circuit of claim 1, wherein the variable delay circuit comprises:
a primary counter for counting times of receiving the output clock signal to generate a count;
an auxiliary variable delay circuit, comprising:
a Digital/Analog Converter (DAC), for converting the count to an analog signal; and
a signal delay circuit for receiving the output clock signal and the analog signal to decide the second delay according to the analog signal so as to update the feedback clock signal.

8. The clock signal generating circuit of claim 1, wherein the main delay circuit comprises an output end for outputting a saw-tooth waveform signal.

9. A clock signal generating circuit with spread spectrum for EMI reduction, comprising:
a main delay circuit; and
a variable delay circuit;
wherein an output end of the main delay circuit is connected to an input end of the variable delay circuit, and an output end of the variable delay circuit is connected to the output end of the main delay circuit to construct a signal loop for generating an output clock signal;
wherein signal propagation from an input end of the main delay circuit to the output end of the main delay circuit requires a first delay, and signal propagation from the input end of the variable delay circuit to the output end of the variable delay circuit requires a second delay;
wherein the second delay varies periodically, and the second delay is shorter than the first delay.

10. The clock signal generating circuit of claim 9, wherein the variable delay circuit comprises a counter for counting times of receiving the output clock signal to generate a count, and the second delay is positively correlative to the count.

11. The clock signal generating circuit of claim 9, wherein the main delay circuit comprises an output end for outputting a saw-tooth waveform signal.

12. A power converting system with spread spectrum for EMI reduction, comprising:
a power switch, electrically connected to a power;
a duty ratio regulator, for generating a switch control signal having an adjustable duty ratio in order to control the power switch, the duty ratio regulator comprising:
the clock signal generating circuit of claim 11; and
a comparator, for comparing a duty voltage and the saw-tooth waveform signal generated by the clock signal generating circuit to generate the switch control signal.

13. A method for generating an output clock signal with spread spectrum for EMI reduction, the method comprising:
providing a signal loop to generate the output clock signal; wherein the signal loop is constructed by a first propagation path and a second propagation path; in which signal propagation in the first propagation path requires a first delay and signal propagation in the second propagation path requires a second delay; in which the first delay is longer than the second delay; and
periodically varying the second delay to change frequency of the output clock signal.

14. The method of claim 13, further comprising:
counting times of receiving the output clock signal to vary the second delay.

15. The method of claim 14, further comprising:
providing a reference clock signal, wherein a cycle time of the reference clock signal is not greater than the second delay; and
after receiving the output clock signal, comparing times of receiving the reference clock signal and the times of receiving the output clock signal.

16. The method of claim 14, further comprising:
converting the times of receiving the output clock signal to an analog signal to control the second delay.
